(19) United States
(12) Patent Application Publication
(10) Pub. No.: US 2025/0343385 A1
(43) Pub. Date: Nov. 6, 2025

(54) SMART PANEL ADAPTER FOR CONNECTING A SMART PANEL TO AN ELECTRICAL METER SOCKET

(71) Applicant: Span.IO, Inc., San Francisco, CA (US)

(72) Inventors: Archan Rao, San Francisco, CA (US); Hans von Clemm, San Francisco, CA (US); Jason Fisher, San Francisco, CA (US); Eric Tong Chiang, Oakland, CA (US); Nicholas Schlessinger, San Mateo, CA (US)

(21) Appl. No.: 19/266,386

(22) Filed: Jul. 11, 2025

Related U.S. Application Data
(63) Continuation of application No. PCT/US2025/027899, filed on May 6, 2025.
(60) Provisional application No. 63/643,385, filed on May 6, 2024.

(51) Int. Cl. H01R 31/06; G01R 22/06; G01R 22/10; H01R 13/64

(52) U.S. Cl. CPC H01R 31/06; G01R 22/065; G01R 22/10; H01R 13/64

(57) ABSTRACT

To simplify the installation of smart panels, a smart panel adapter is provided. The adapter connects to the meter socket in place of the electrical meter. The smart panel adapter also has a power connection to the smart panel in order to route electrical power to the panel. In this way, the smart panel may be easily installed in the electrical distribution system at the site.

### CROSS-REFERENCE TO RELATED APPLICATION(S)

This application is a continuation of International Application No. PCT/US2025/027899, “Smart panel adapter for connecting a smart panel to an electrical meter socket,” filed May 6, 2025; which claims priority to U.S. Provisional Patent Application No. 63/643,385, “Electrical meter intercept connection device,” filed May 6, 2024. The subject matter of all of the foregoing is incorporated herein by reference in their entirety.

### BACKGROUND

### 1. Technical Field

This disclosure relates generally to electrical panels with intelligence (smart panels) and, more particularly, to the connection of smart panels to sockets for electrical meters.

### 2. Description of Related Art

Electrification will continue to add massive amounts of demand to electrical distribution. Estimates are that net distribution capacity in the U.S. will increase significantly to support fully renewable energy sources. The current distribution system and site-level (e.g. building) wiring are not well instrumented and not easily controllable. They are not well suited to implement sophisticated, intelligent management of electrical power.

Smart panels are electrical panels with intelligence that allow for more sophisticated monitoring and control of electrical power distribution. Smart panels may also facilitate the addition of new sources and loads to an existing site. New constructions may include smart panels as part of the original electrical power distribution system. However, existing structures typically already have more conventional electrical panels. These panels include hardware circuit breakers to provide overcurrent protection, but they are not capable of much more.

As a result, there is a large market opportunity to retrofit existing structures with smart panels, particularly as part of projects that are otherwise increasing or upgrading the electrical system at a site. However, one of the barriers to more widespread adoption of smart panels is the difficulty and time it takes for a smart panel to be installed. The installation may take many hours and require a trained professional electrician. This will extend the schedule and increase the cost of any upgrade project. Thus, there is a need to simplify the task of installing smart panels, particularly as retrofits to existing structures. There is also a need to reduce the human skill and labor required to perform such an installation.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIG. 1 (prior art) is a diagram of an electrical meter connected to a meter socket.

FIGS. 2-4 are diagrams of different smart panel adapters connected to a meter socket in place of the electrical meter.

FIG. 5 is a single line diagram of a smart panel adapter connected to a meter socket.

FIG. 6 shows a smart panel adapter retrofit to an existing meter socket.

FIGS. 7A-7B are perspective views of a smart panel adapter.

FIG. 7C is a perspective view of a safety mechanism for a smart panel adapter.

FIG. 7D is a perspective view of a smart panel adapter with power cable installed.

FIG. 8A is a cross-section of a wire harness containing service conductors and load conductors.

FIG. 8B is a cross-section of a wire harness containing service conductors and data conductors.

FIG. 9 is a diagram of a smart panel adapter with a data connection to the smart panel.

FIG. 10 is a block diagram of a smart panel.

### DETAILED DESCRIPTION OF THE PREFERRED EMBODIMENTS

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Aspects of the present disclosure relate to a smart panel adapter for connecting a smart panel to an electrical meter socket. At most sites, an electrical meter measures the electrical power provided by a utility service to the electrical loads at the site. The electrical power from the utility service enters through a service panel that includes a meter socket, and the electrical meter is connected to the meter socket. Electrical power from the utility service enters the service panel/socket, flows through the electrical meter connected to the socket, and then exits the service panel/socket and flows to the loads at the site.

To simplify the installation of smart panels, a smart panel adapter is provided. The adapter connects to the meter socket in place of the electrical meter. The smart panel adapter also has a power connection to the smart panel in order to route electrical power to the panel. In this way, the smart panel may be easily installed in the electrical distribution system at the site.

The adapter may have an intercept configuration, in which the adapter has its own meter socket. The meter is connected to this socket on the adapter and continues to provide the metering function for the site. The adapter is interposed between the original meter socket (on the service panel) and the electrical meter in its new location. The adapter intercepts electrical power flowing between the two and routes some/all of that power to the smart panel.

Alternatively, the adapter may have a cap configuration, in which there is no additional connection for the electrical meter. The adapter provides the connection to the smart panel, but otherwise caps the meter socket. The metering function may be included in the smart panel so that a separate meter is no longer required.

Within the adapter, the smart panel and the existing load at the site may be connected in series or in parallel. In a series connection, electrical power flows through the smart panel and then to the existing load. In a parallel connection, electrical power flows in parallel and is divided between the smart panel and the existing load. The smart panel may also be used to connect new loads and sources to the electrical distribution system.

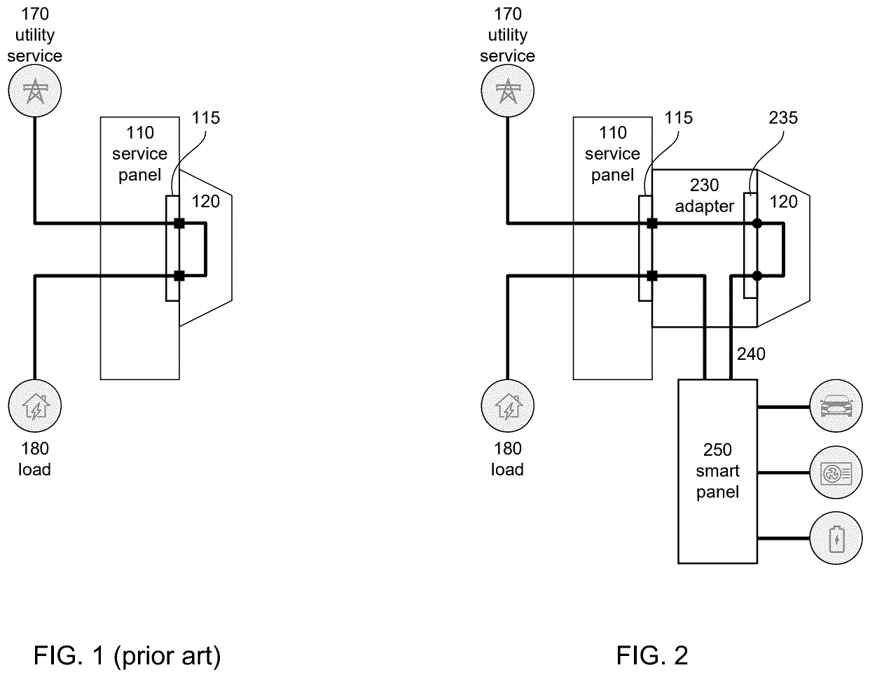

By way of example. FIG. 1 (prior art) is a diagram of an electrical meter connected to a meter socket, and FIG. 2 is a diagram of the same system but with a smart panel adapter connected to the meter socket in place of the electrical meter. FIG. 1 shows a service panel 110 which provides the interface between a utility service 170 and the load 180 at a site. The service panel 110 includes an electrical meter socket 115, which provides an interface to connect an electrical meter 120. In FIG. 1, the connection between the socket 115 and the meter 120 is represented by the two black squares. When the meter 120 is connected, electrical power flows from the utility service 170, through the meter socket 115, through the meter 120, back through the socket 115 and on to the load 180. The load 180 is represented in FIG. 1 by a single symbol, but it may include distribution with branch circuits, other panels, etc. Some of these may be contained in the service panel 110. For example, a single enclosure may include both the meter socket 115 and a bus structure for distribution to branch circuits.

FIG. 2 is a diagram of the electrical distribution system of FIG. 1 but retrofit with a smart panel adapter. In this example, the adapter 230 connects to the meter socket 115 in place of the meter 120. The adapter 230 is also connected to a smart panel 250 by a power connection 240. FIG. 2 shows an intercept configuration, in which the adapter 230 has its own meter socket 235 with connections shown as two black dots. The meter 120 is connected to this socket 235. The adapter 230 is interposed between the original socket 115 and the meter 120.

Electrical power flows as follows. The paths to the left of the original socket 115 are unchanged, except that the adapter 230 takes the place of the meter. Electrical power flows from the utility service 170 through the meter socket 115 to the adapter 230. In the reverse direction, electrical power flows from the adapter 230 through the meter socket 115 to the load 180. The adapter 230 is a way to connect the smart panel 250 to the distribution system, so there is a new path for electrical power to flow from the adapter 230 over the power connection 240 to the smart panel 250.

FIG. 2 shows a series connection for the smart panel 250 and load 180. In this case, after flowing through the meter 120, the adapter 230 routes electrical power first though the smart panel 250 and then to the load 180 (via socket 115). When connected in this configuration, electrical power flows through the panel before flowing to the other circuits at the site. This is useful for metering, whole-home backup, etc. The smart panel 250 can also function as the main service disconnect for the site.

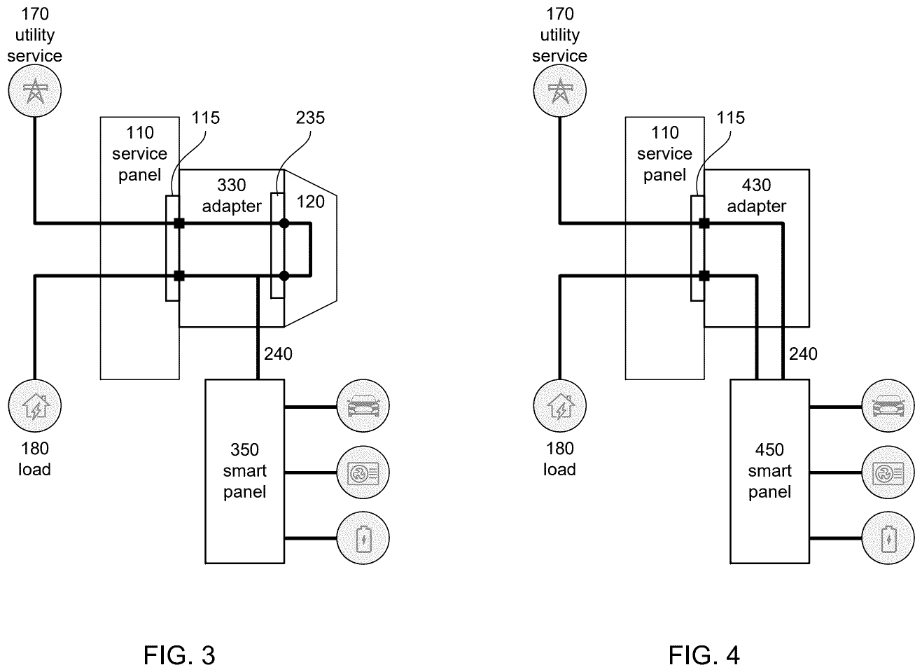

FIG. 3 shows a parallel connection for the smart panel 350 and load 180. FIG. 3 is the same as FIG. 2, except that the adapter 330 routes electrical power in parallel to both the smart panel 350 and to the load 180. A parallel connection simplifies the electrical wiring by allowing leverage of the existing EGC (equipment grounding conductor) that is landed in the homes main service panel and by eliminating the need to separate neutral and ground conductors in the existing service panel.

FIG. 4 is the same as FIG. 2 (series connection) but the adapter 430 is a cap configuration rather than an intercept configuration. There is no meter socket on the adapter 430 and no electrical meter connected to the adapter 430. Instead, electrical power flows directly to the smart panel 450. FIG. 4 shows a series connection between the smart panel 450 and load 180, although the two could also be connected in parallel. In FIG. 4, the electrical power from the utility service 170 for the entire site flows through the smart panel 450. The smart panel 450 may include the electrical meter function, rather than having a separate meter as in FIG. 2. This may be implemented as part of the smart panel functionality, or a conventional meter may be combined with the smart panel in a single enclosure.

As in FIG. 2, the smart panel 450 may also include a grid disconnect which would then disconnect the load 180 from the utility service 170 because the smart panel 450 and load 180 are connected in series. The load 180 may continue to operate if other power sources are connected. For example the smart panel 450 may be connected to solar panels, battery storage or generator backup.

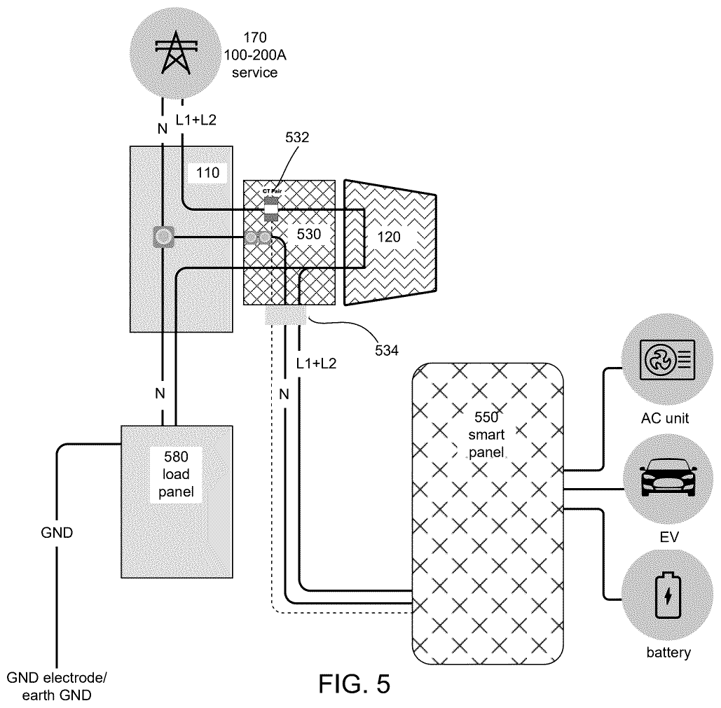

FIG. 5 is a line diagram of the parallel configuration of FIG. 3. FIG. 5 shows a two-phase circuit with L1, L2 and N. The L1 and L2 lines are routed from the utility service 170 to the service panel 110. L1 and L2 are routed through the adapter 530, to the utility meter 120 and back to the adapter 530. From there, L1 and L2 are split and routed in parallel to the original load panel 580 which feeds the existing circuits, and also to the new smart panel 550 which may connect to additional loads or sources, such as an AC unit, electric vehicle or battery. A quick connect harness 534 is used to route the L1 and L2 lines from the adapter 530 to the smart panel 550. The N lines are routed accordingly. The configuration of FIG. 5 also includes a current sensor 532 to measure the total electricity entering the site. The dashed line in FIG. 5 indicates that the current sensor measurements are available to the smart panel 550.

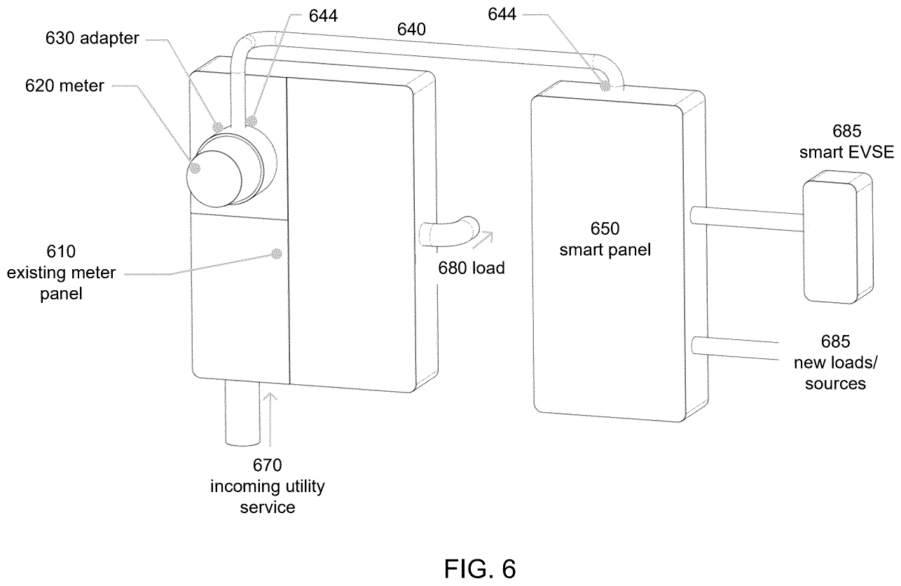

FIG. 6 shows a smart panel adapter retrofit to an existing meter socket. The system before retrofit included a service panel 610 with electrical meter 620, incoming utility service 670 and existing electrical load 680. In the retrofit, the meter 620 is removed from the panel 610, and the smart panel adapter 630 is installed in its place. Adapters 630 may be compatible with ring and ringless style meter enclosures. A smart panel 650 is mounted in close proximity to the service panel 610, for example using a cleat like mechanism. The smart panel 650 is connected to the existing electrical distribution system by power connection 640. In some cases, the connection 640 may be prewired, so that the adapter 630, connection 640 and panel 650 arrive on site already connected. Alternatively, the connection 640 may be a removeable cable with plugs 644 on one or both sides, as shown in FIG. 6. The cable may be installable without requiring an electrician. FIG. 6 shows the smart panel 650 connected to additional loads and sources 685, either hardwired or through receptacles.

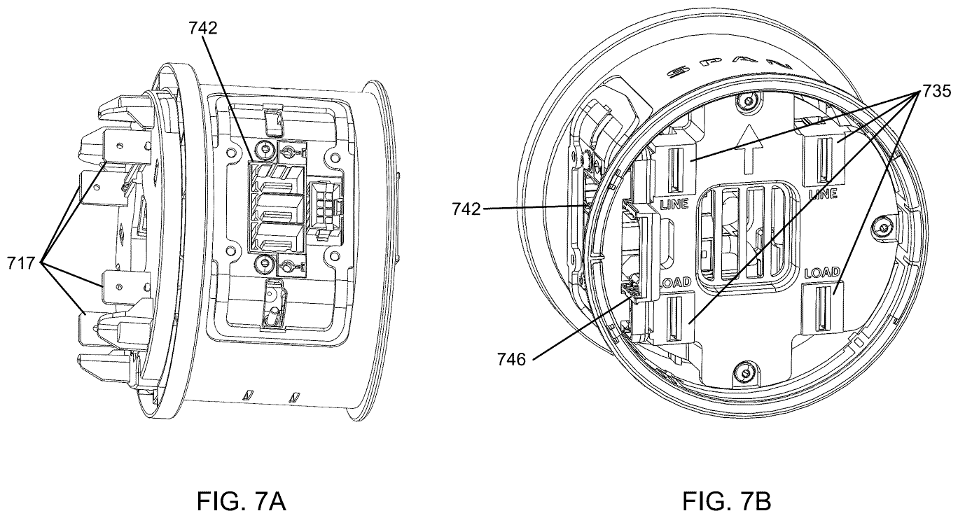

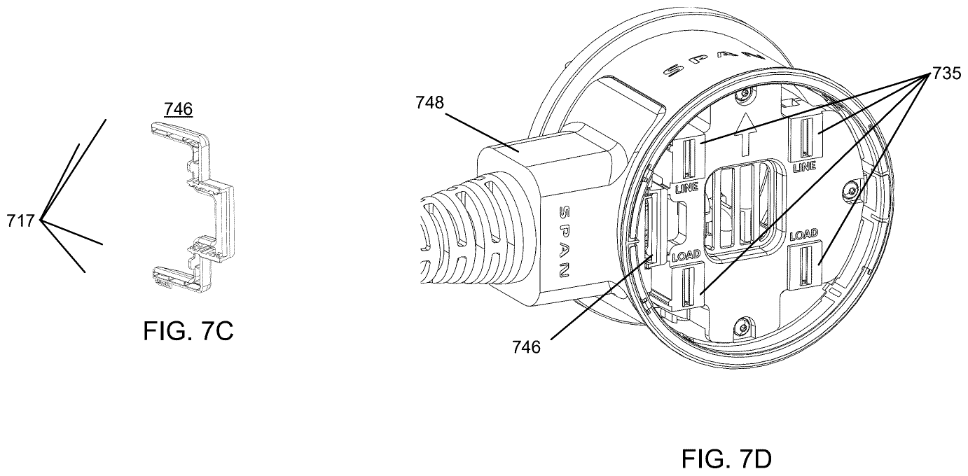

FIGS. 7A and 7B show left side and front perspective views of a smart panel adapter. This adapter is an intercept configuration. The four connections 717 to the existing meter socket can be seen in FIG. 7A. The additional meter socket 735, labelled LINE and LOAD within the adapter, can be seen in FIG. 7B. The cable to the smart panel connects to power socket 742.

This example also includes a safety mechanism 746, which in this example is a sliding wedge mechanism. FIG. 7C is a perspective view of the safety. The sliding wedge mechanism is used to enforce an installation order and improve product safety. The wedge 746 is able to slide through a space created by the smart panel adapter and the front-facing insert. The motion of the wedge is constrained on one end by a spring-loaded pin and on the other by the shape of the adapter and insert. When the power cable is not connected to the smart panel adapter, as shown in FIG. 7B, the raised un-loaded pin prevents the wedge 746 from sliding through the space into the body of the adapter. The wedge 746 protrudes above the surface of the adapter, which prevents installation of the electrical meter into the adapter.

However, when the power cable 748 is plugged into the smart panel adapter, as shown in FIG. 7D, raised portions of the cable shroud depress and load the pins. This allows for free movement of the wedge 746 into the body of the adapter. In this state, the electric meter may be installed into the meter socket 735 because the wedge 746 now sits flush with the insert.

In another embodiment, the wedge passes through openings in the power cable shroud and further secures it to the smart panel adapter, preventing removal of the cable until the meter is uninstalled. These embodiments prevent improper assembly order by mechanically enforcing installation of the power cable into the smart panel adapter before the meter, or conversely enforcing uninstallation of the meter before the power cable is removed. In either case, overall touch safety is improved because the power socket for the power cable will not be energized when the cable is not connected to the adapter.

Connections to the smart panel may include data connections in addition to power connections. The data connections may be low voltage. The power connections may be classified as either service conductors or load conductors. Service conductors are power connections that are upstream of the home's main disconnect. These connections may be contained within a single cable assembly, for example connection 640 in FIG. 6. The wire bundle may provide barriers to separate the different types of conductors, for example separating the service conductors from other conductors.

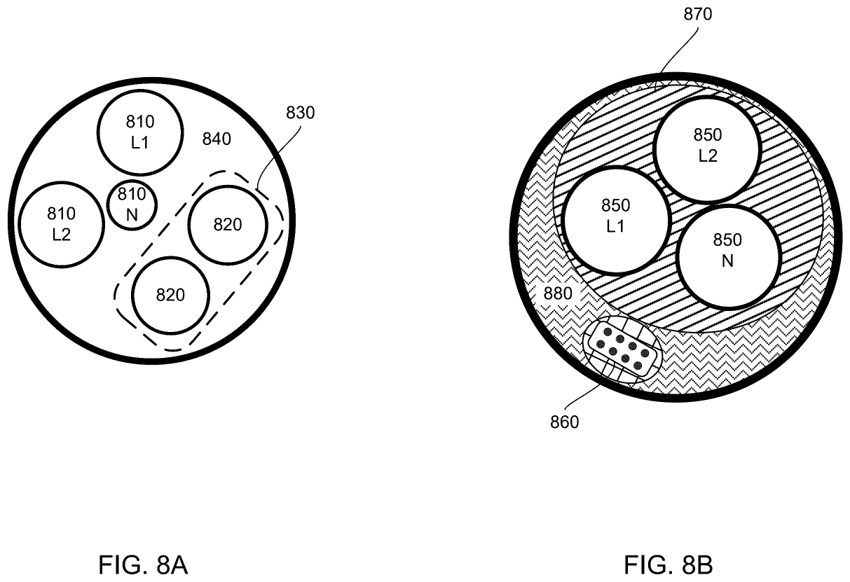

FIG. 8A is a cross-section of a wire harness that contains both service conductors and load conductors. Conductors 810 are L1, L2 and N service conductors. Conductors 820 are the load conductors. The wire harness includes a barrier 830, such as metal, to separate the service conductors 810 and the load conductors 820. It may also include insulation 840. The insulation may be electrically insulating but thermally conducting to help in thermal management. Epoxy resins may be used for this purpose.

FIG. 8B is a cross-section of a wire harness that contains both power conductors (service or load) and also data connections, such as low voltage conductors. Conductors 850 are L1, L2 and N power conductors. Assembly 860 contains the data conductors. The wire harness includes a barrier 870, such as metal, to separate the power conductors 850 and the load conductors 860. It may also include insulation 880.

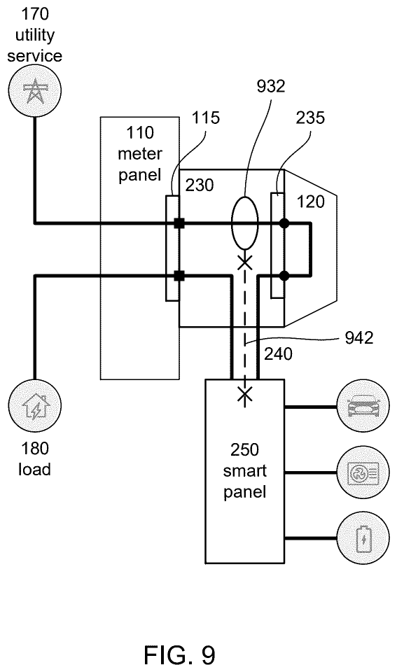

Fuses may also be used to protect electrical connections. FIG. 9 shows the series intercept configuration of FIG. 2, but with a low voltage data connection 942 between the smart panel adapter 230 and the smart panel 250. For example, the adapter 230 may include a current sensor 932 that senses the current flowing in from the utility service. This measurement may be sent to the smart panel for use in controlling the electrical distribution system. Other examples include temperature sensors and low voltage control wires. If the electrical meter 120 has network access, that may be passed to the smart panel 250 by a communications path through the adapter 230. If the utility company communicates to electrical meters via a mesh network, then such a communications path provides the smart panel with access to the mesh network.

Fuses may be located at the X's in the adapter 230 and/or in the smart panel 250. This will protect low voltage conductors from shorts to service and load conductors. In the event of a fault, the fuse will prevent the power conductors from damaging sensitive equipment or causing electric shock. Alternatively, the data link may be made wirelessly.

The technology described in this disclosure can reduce installation time to one hour or less and some versions can be installed by an untrained service technician. This reduces cost and simplifies retrofit. Compared to a conventional “dumb” panel, a smart panel provides software programmable monitoring and control of the electrical distribution system. Control loops generally will include sensor(s), logic and actuator(s), although not all of these need be contained within the smart panel. The smart panel will also have network access, for example to report data, access off-site resources such as computing or additional data, and to access components external to the smart panel. The smart panel may also allow for the addition of new loads, such as an EVSE (electric vehicle supply equipment), and new sources, such as a behind-the-meter battery or solar system, without having to find space for these in an existing panel or rewire a new electrical panel for these additional loads. In some configurations, it can also disconnect the site from the grid. The smart panel may also talk to inverters for islanding purposes.

As a result, homeowners and others will be able to further electrify their sites with multiple new appliances using a cost-effective method for retrofit installations. Smart panels can allow the connection of multiple loads and can provide for enhanced visibility and control of appliances by smart meter owner/operators. Certain versions may also include quick-connect high voltage/current connection points to quickly install new electric loads. These fittings may also contain low voltage communications wires. This approach may also provide a grid disconnect switch (MID) to the home for islanding.

This approach can also address other problems, for example the following.

Meter socket adapters require a neutral connection which does not come off the standard utility socket form (1S, 2S, 16S). This neutral connection must be wired into the existing panel. One embodiment of this approach could include a neutral tap that comes off of the ring of the meter socket, or a specialized lug that pierces the insulation of the feeder neutral connection.

Getting the smart electrical panel installed at the site is only the first hurdle to electrification of that home. Next an electrician must install the equipment, like an EVSE, heat pump, or electric water heater. The technology described herein may include additional quick-connect electrical hardpoints that are pre-wired to circuit breakers in the smart electrical panel. This would remove the need of an electrician from the large electrification projects needed to electrify a home because a homeowner could simply get the equipment, be it a battery, a solar system, a heat pump, etc., and safely plug it in to an external port on the electrical panel. This connection can include high power connections as well as low voltage communications conductors in a single body, to further simplify these projects.

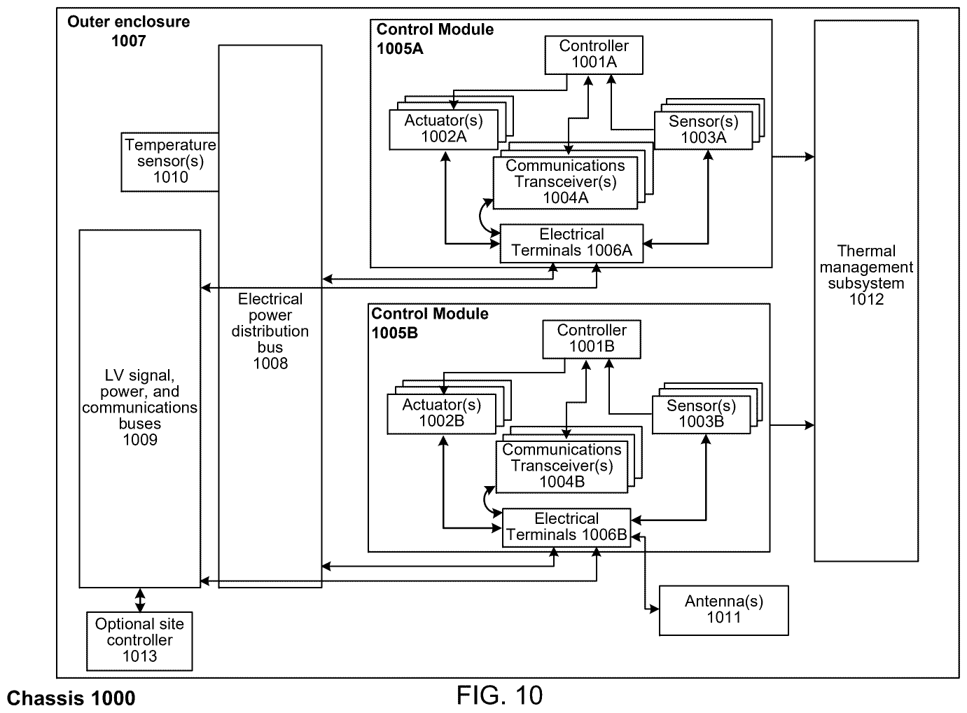

FIG. 10 shows an example of an architecture for smart panels. The smart panel may be architected as a set of control modules installed into a chassis at predefined attachment points. FIG. 10 is a block diagram of a chassis 1000. A modular chassis will have some benefits to customers and installers, including the following. Among other components, the chassis 1000 includes two control modules 1005 (the reference numbers in FIG. 10 include “A” and “B” to differentiate the two modules). As described with respect to FIG. 10, each control module 1005 includes a controller 1001, actuator(s) 1002, sensor(s) 1003, communications transceiver(s) 1004, and electrical terminals 1006. The reference numbers in FIG. 10 include “A” and “B” to differentiate the components across the two control modules.
Serviceability: If a single component such as a relay fails, it will be substantially less effort to unwire and replace one module than an entire product such as an entire panel, or a monolithic control subassembly. Electricians will appreciate the modular design for this reason.
Customizability: A modular architecture allows customization of panels and similar products to sites, allowing purchasers to select between multiple chassis sizes and to specify which modules are installed. This can either be done using a configurator UI or with installers actually assembling modules into a chassis on site to build custom panels on the fly.
Hardware upgrades: Even if hardware has not failed, customers may choose to upgrade modules to receive new capabilities (for example to adopt new sensing, safety features, or communications protocols). A modular architecture makes such intervention affordable.
“Power electronics in the panel”: The modular chassis design supports inclusion of different modules, including power electronics.

The electrical panel shown in FIG. 10 includes the following components:
Enclosure 1007: An outer enclosure responsible for protecting against dust and water ingress, providing impact resistance, and performing electromagnetic shielding as necessary. It may be made of sheet metal, although in some implementations it may be composed of plastic, optionally foil-lined for EMI.
Sub-enclosure (not shown): The enclosure of a control module contained within the chassis 1000. It may be plastic and may also be foil-lined. It may be protected from water and/or dust ingress using e.g. silicone gasket seals.
Electrical power distribution bus 1008: Electrical bus structure to which modules are attached by e.g. screw bolts.
Low voltage (LV) signal and communications buses 1009: The chassis 1000 also contains a low-voltage bus (different from the electrical power distribution bus), which may be implemented as a harness or a long PCBA with regularly spaced header connectors. This bus distributes logic power generated by one or more modules, one or more communications bus (e.g. CAN, possibly redundant), and/or one or more digital signals. It serves as an intra-panel communications network between the modules in the panel.

Digital signals may include:
SYNC, a pulse train for synchronizing digital sampling;
FAULT, an active-low digital signal which indicates a hardware or software failure for which modules should fail safe;
OVERRIDE, an active-high digital signal, possibly redundant, which indicates that a user override has been set, for example indicating that all modules should close their relays.
Antennas 1011: The chassis may contain external antennas which connect to installed control modules to increase their RF transmit range.
Temperature sensor 1010: The buswork in the chassis may be monitored for over temperature, with some means of routing the signal back to one or more control modules (e.g. a temperature sensor may have a pigtail harness which connects to a pluggable PCB connector on the front of the chassis' head module).
Optional site controller 1013: A chassis may have a socket into which a site controller/gateway may be installed. This socket may instead be located on the head control module.
Thermal management subsystem 1012: A subassembly of thermal conductors, heatsinks, fins, and/or circulation or ventilation fans which serve to transfer heat from the enclosure.
Control Modules 1005: A device capable of providing a function such as metering, relay control, or power conversion. Control modules may have multiple functions (e.g. metering and relay control). In some cases, control modules may have only one of sensing, actuation, or conversion capabilities.

Control modules include AC chassis modules (i.e., housed in the electrical panel), such as Branch Module, Panel Control Module, and MID/Main Breaker Module. They may also include AC/DC chassis modules.

The Panel Control Module acts as a hub for the chassis modules installed in an electrical panel. For example, it maintains a registry of the modules installed in the panel. It may provide controls to the installed modules and aggregate data from the modules. The LV spine 1009 may be used to communicate with these other modules. The Panel Control Module may also perform Head functions. In some instantiations, the module includes communications transceivers such as e.g. RS485 or CAN for communication to third party devices such as solar inverters, batteries, generators. In some instantiations, the module includes low voltage relays and switches, e.g. to interrupt the 24VAC control line to HVAC systems. In some instantiations, the module includes meters or sensors which accept electrical signals from field wired connectors, e.g. a pluggable connector for externally placed CTs. In some instantiations, meters may measure voltage from the module's contact pads and current from externally placed coverage targets. In others, voltage may be externally provided or selectable between the two by means of e.g. installer-accessible switches or field installable jumpers. Being able to read and send dry contact states, communicate on CAN, and do auxiliary metering directly from the panel itself make the panel well-suited to integration with other third-party equipment.

The control modules in FIG. 10 show some of the following hardware components, but not all components will be in every control module.
Controller 1001: A microcontroller, DSP, or other such software programmable electronic controller. Typically one per module, although some modules may include additional microcontrollers for additional functionality or for redundancy for purposes of safety. Executes control algorithms, reads sensors, manages actuators, and implements communications to other modules and the Site Controller.
Sensor(s) 1003: e.g. a current transducer (typically as a current transformer plus burden resistor) or voltage transducer. May include additional chips or modules for sensor processing, e.g. an energy metering ASSP such as the ST Microelectronics STPM34.
Actuator(s) 1002: A physical actuator such as an electromechanical relay which allows control over the flows of electrical power in an electrical distribution system such as the wiring in a building.
Communications Transceiver(s) 1004: Transceivers for wired communications protocol and/or wireless/powerline communications means, e.g. a CAN controller+transceiver; an Ethernet MAC and PHY; or a G3-Hybrid modem with a G3-PLC line driver and/or a 900 MHz radio+antenna.
“Spine” Connector (not shown): A field-wired connector which carries logic power (e.g. 12VDC), wired communications (see below), and other digital/analog signals.
Electrical Terminals 1006: One or more electrical terminals for series (actuation) or parallel (sensing) connection to distribution conductors. May include stabs for plug-on molded-case circuit breakers, lugs, threaded studs, solder pads, small-gauge pluggable PCB connector headers (e.g. Phoenix LPC), or other types of terminal.

The electrical terminals for modules in the panel may have the following. Each module has standard rear-facing busbar mount pads with captive screw fasteners. The Head Module has a series of metering ports, as well as ports for external communications. The Branch Module has circuit breaker stabs. The Main Breaker/MID module has studs to mount either a 200A main breaker or lugs.
Power converter (not shown): This could be a high-voltage to low-voltage converter for producing logic power from distribution conductors, such as a 120VAC-to-12VDC rectifier. It could also be a high-voltage to high-voltage power converter, e.g. an AC to DC inverter (e.g. a photovoltaic solar inverter) or an isolated DC-DC converter (e.g. a photovoltaic solar maximum-power-point tracker (MPPT)).
Energy Storage (not shown): An optional capacitive reserve. Used to store energy such that the device can fail safe even if the central power supply fails suddenly.
PMIC (not shown): An optional power management IC, shown primarily to indicate the receipt of logic power from the Connector(s).

Although the detailed description contains many specifics, these should not be construed as limiting the scope of the invention but merely as illustrating different examples. It should be appreciated that the scope of the disclosure includes other embodiments not discussed in detail above. Various other modifications, changes and variations which will be apparent to those skilled in the art may be made in the arrangement, operation and details of the method and apparatus disclosed herein without departing from the spirit and scope as defined in the appended claims. Therefore, the scope of the invention should be determined by the appended claims and their legal equivalents.

What is claimed is:

1. An electrical distribution system comprising:
a meter socket connected to a utility service and to an electrical load and configured to connect to an electrical meter wherein, when the electrical meter is connected, electrical power flows from the utility service through the meter socket to the electrical meter and back from the electrical meter through the meter socket to the electrical load;
a smart panel adapter connected to the meter socket in place of the electrical meter; and
a smart panel with a power connection to the smart panel adapter; wherein electrical power flows from the utility service through the meter socket to the smart panel adapter, and from the smart panel adapter over the power connection to the smart panel.

2. The electrical distribution system of claim 1, wherein the smart panel provides software programmable control of the electrical distribution system.

3. The electrical distribution system of claim 1, wherein the smart panel comprises a chassis containing a plurality of field-replaceable control modules.

4. The electrical distribution system of claim 1, wherein the smart panel comprises:
a chassis comprising:
a bus structure that receives electrical power, and
a plurality of predefined attachment points for installation of field-replaceable control modules;
a field-replaceable branch module installed at one of the attachment points with electrical connection to the bus structure, the branch module distributing electrical power from the bus structure to a branch circuit and providing sensor, processor and/or actuator capabilities for the branch circuit;
a field-replaceable panel control module installed at one of the attachment points with electrical connection to the bus structure, wherein the panel control module maintains a registry that includes the installed branch module; and
an intra-panel communications network, over which the panel control module communicates data and control with the branch module.

5. The electrical distribution system of claim 1, wherein the smart panel adapter comprises a second meter socket connected to the electrical meter, and the smart panel adapter is interposed between the meter socket connected to the utility service and the electrical meter.

6. The electrical distribution system of claim 1, wherein the smart panel adapter caps the meter socket without any connection to the electrical meter.

7. The electrical distribution system of claim 1, wherein the smart panel and the meter socket are connected in series, and the smart panel adapter routes electrical power first through the smart panel via the power connection and then to the electrical load via the meter socket.

8. The electrical distribution system of claim 1, wherein the smart panel and the meter socket are connected in parallel, and the smart panel adapter routes electrical power in parallel to both the smart panel via the power connection and to the electrical load via the meter socket.

9. The electrical distribution system of claim 1, further comprising: a data connection between the smart panel and the smart panel adapter.

10. A smart panel adapter that is configured to connect to a meter socket in place of an electrical meter wherein, when the smart panel adapter is connected to the meter socket and also connected to a smart panel: electrical power flows from a utility service through the meter socket to the smart panel adapter, and from the smart panel adapter over a power connection to a smart panel.

11. The smart panel adapter of claim 10, further comprising: a second meter socket configured to connect to the electrical meter, wherein the smart panel adapter is interposed between the meter socket connected to the utility service and the electrical meter.

12. The smart panel adapter of claim 11, further comprising:
a power socket configured to connect to a removeable power cable for the smart panel; and
a safety that prevents connection of the electrical meter to the smart panel adapter when the power cable is not connected to the power socket.

13. The smart panel adapter of claim 10, wherein the smart panel adapter caps the meter socket without any connection to the electrical meter.

14. The smart panel adapter of claim 10, wherein the connection to the smart panel and the connection to the meter socket are connected in series.

15. The smart panel adapter of claim 10, wherein the connection to the smart panel and the connection to the meter socket are connected in parallel.

16. The smart panel adapter of claim 10, wherein the smart panel adapter is a retrofit to the meter socket.

17. The smart panel adapter of claim 10, further comprising: a power socket configured to connect to a removeable power cable for the smart panel.

18. The smart panel adapter of claim 17, wherein the power cable is connectable to the power socket without an electrician.

19. The smart panel adapter of claim 10, wherein the smart panel adapter is compatible with ring style meter enclosures.

20. The smart panel adapter of claim 10, wherein the smart panel adapter is compatible with ringless style meter enclosures.
